(19) United States
(12) Patent Application Publication
(10) Pub. No.: US 2003/0161490 A1
(43) Pub. Date: Aug. 28, 2003

(54) Electrical appliance, in particular, a ventilator hood and method for operating the appliance

(76) Inventor: Jens Maase, Regensburg (DE)

Correspondence Address: LERNER AND GREENBERG, P.A., Post Office Box 2480, Hollywood, FL, 33022-2480, US

(21) Appl. No.: 10/375,527

(22) Filed: Feb. 27, 2003

(30) Foreign Application Priority Data
Feb. 27, 2002 (DE) 102 08 469.6

(51) Int. Cl. H04R 3/00; H03G 3/20

(52) U.S. Cl. 381/110

(57) ABSTRACT

A household appliance, in particular, a ventilator hood, includes a voice operating unit with a microphone and a sensor serving as a motion detector that switches on the microphone only during reception of a signal. Also provided is a method for operating the appliance and hood including the steps of detecting movement of a person or an object with a motion detector generating a signal when motion is detected, switching on a microphone for a prescribed period of time dependent upon the signal, analyzing voice signals detected by the microphone, and passing the detected voice signals to a voice evaluation unit only when a voice is detected and activating a function of the household appliance.

### BACKGROUND OF THE INVENTION

1. Field of the Invention

The invention relates to an electrical household appliance, in particular, a ventilator hood, with a voice operating unit having a microphone and a method for operating the appliance.

International publication WO 01/59763 A1 discloses an electrical appliance with a voice input unit. Connected downstream of the voice input unit is a voice processing unit that uses spoken input commands to derive control signals for controlling functions of the household appliance. An operational status detection unit is provided that detects the operational status of the household appliance or other noise sources, and reports to the voice processing unit. The voice processing unit undertakes an interference noise correction only if a noise source is switched on. The prior art method for voice input with correction of interference signals is characterized in that the operational status of at least one noise source that interferes with the voice input is interrogated during the voice input for controlling an appliance, and in that the voice processing unit undertakes an interference noise correction only if a noise source is switched on. Thus, if a voice signal is submitted to the voice processing unit for recognition, an attempt is not made in each case to undertake an interference noise correction. This leads to an improvement in the voice recognition in all cases in which the voice signal is not loaded at all by interference noises. This is because the quality of the voice signal is reduced by the effort to remove nonexistent interference noise from the voice signal, or to take correcting account of it.

### SUMMARY OF THE INVENTION

It is accordingly an object of the invention to provide an electrical appliance, in particular a ventilator hood and a method for operating the appliance that overcome the hereinafore-mentioned disadvantages of the heretofore-known devices and methods of this general type and that improves the reception of voice signals in the household field based upon other data.

With the foregoing and other objects in view, in an electrical household appliance, there is provided, in accordance with the invention, a voice-activation unit including a voice operating unit having a microphone and a motion detector for detecting motion and generating a motion detected signal when motion is detected, the motion detector connected to the microphone and supplying the motion detected signal to the microphone, the microphone being switched on only during reception of the motion detected signal.

In the case of an electrical household appliance according to the invention, in addition a motion detector is associated with the household appliance, and the microphone can be switched on only during reception of a signal from the motion detector.

Misuse of the voice input unit is greatly reduced by the intervention of the motion detector.

Specifically, when voice operating units are used the technically achievable reliability of the recognition of commands varies depending on the type of voice operating unit, but is specified by the manufacturers as being 95% at best. This means that the frequency of non-recognition or of erroneous recognition of a command is 5% under ideal conditions. This value is further increased by extraneous noises and other sources of influence such as, for example, echoing, reflections in the room, a radio that is switched on, etc. Because of these conditions, voice control systems cannot be used in safety-relevant applications. It is precisely here that the invention provides a remedy by pursuing an entirely different way of obtaining information. As a result of combining a motion detector with the voice input unit, the voice evaluation unit becomes active only when both a movement of a body emitting infrared radiation, and a voice signal are present.

The use of a motion detector prevents the switching on of a body emitting infrared radiation, for example, an incandescent lamp below the ceiling of the room, from activating the microphone, and the latter from then picking up unwanted signals and switching on or switching off the household appliance erroneously.

On the other hand, an object that is moving in the room, for example, a ball thrown by a child, cannot switch on the voice operating unit because, in an advantageous development of the invention, the sensor simultaneously expects the presence of an infrared source in addition to the movement signal. Consequently, only a person can switch on the microphone of the voice operating unit through the sensor and, subsequently, control the device with the aid of voice signals.

In accordance with another feature of the invention, the motion detector is an infrared signal receiver. The motion detector is advantageously a sensor that reacts to signal changes.

In accordance with a further feature of the invention, the motion detector activates a timer that sets the microphone for a preselected on period. The microphone, thus, expects that a voice command will be input within a specific time after it has been activated. The voice operating unit is actuated only when the combination of movement of a person and subsequent inputting of a voice command is present. As a result, even inadvertently switching on the microphone cannot lead to maloperation because it is always the combination of movement and voice that is expected to control the household appliance through the voice operating unit.

Particularly suitable is a sensor that has a directional characteristic for its radiation, in particular, infrared radiation. As a result of such a directional characteristic, the sensor switches on the microphone only when the infrared source, or the source emitting a different radiation, appears within a specific area of the room. In particular, the directional characteristic limits detection in a room to above a prescribed height. The activation of the microphone can, therefore, be restricted to the presence of adults, who reach into the detection range of the sensor because of their body size, whereas children cannot trigger the sensor because of their lesser size.

Particularly suitable is a device that additionally has an image detection system, for example, a camera or a CCD array, that recognizes specific persons and is switched on when the motion detector, in particular, the infrared signal receiver, identifies a source that is moving and emitting infrared signals.

In accordance with an added feature of the invention, the motion detector is a sensor reacting to signal changes, in particular, an infrared sensor, and the sensor has a diaphragm through which infrared radiation is passed to the sensor.

In accordance with an additional feature of the invention, the motion detector detects motion in a room and has a directional device limiting detection by the motion detector to a given area of the room.

In accordance with yet another feature of the invention, the microphone is associated with a voice recognition unit that activates the voice evaluation unit only when a voice spectrum stored in the voice recognition unit becomes capable of being recognized by it.

In accordance with yet a further feature of the invention, the voice operating unit has a memory storing at least one voice spectrum, a voice recognition unit is connected to the microphone and to the memory and is programmed to recognize the at least one voice spectrum, and a voice evaluation unit is connected to the voice recognition unit and is activated only when the voice recognition unit recognizes the stored voice spectrum.

With the objects of the invention in view, in a ventilator hood, there is also provided a voice-activation unit including a voice operating unit having a microphone, a motion detector for detecting motion and generating a motion detected signal when motion is detected, the motion detector connected to the microphone and supplying the motion detected signal to the microphone, and the microphone being switched on only during reception of the motion detected signal.

With the objects of the invention in view, there is also provided a method for operating a household appliance, in particular, a ventilator hood, including the steps of detecting movement of a person or an object with a motion detector for detecting motion and generating a motion detected signal when the motion is detected, switching on a microphone for a prescribed period of time dependent upon the motion detected signal, analyzing voice signals detected by the microphone, and passing the detected voice signals to a voice evaluation unit only when a voice is detected and activating a function of the household appliance.

The invention provides a method for switching on a household appliance, in particular, a ventilator hood, with the aid of a microphone, in which a motion detector detects a movement of a person or an object and, based thereon, the microphone is switched on for a prescribable time as a consequence of an output signal generated in the motion detector.

In accordance with a concomitant added mode of the invention, voice signals detected by the microphone are analyzed and, if a voice is detected, the detected voice signals are passed to a voice evaluation unit for evaluation and a function of the household appliance is activated with the voice evaluation unit dependent upon the evaluation of the detected voice signals.

Other features that are considered as characteristic for the invention are set forth in the appended claims.

Although the invention is illustrated and described herein as embodied in an electrical appliance, in particular a ventilator hood and a method for operating the appliance, it is, nevertheless, not intended to be limited to the details shown because various modifications and structural changes may be made therein without departing from the spirit of the invention and within the scope and range of equivalents of the claims.

The construction and method of operation of the invention, however, together with additional objects and advantages thereof, will be best understood from the following description of specific embodiments when read in connection with the accompanying drawings.

### BRIEF DESCRIPTION OF THE DRAWINGS

FIG. 1 is a fragmentary, perspective view of a configuration according to the invention including a ventilator hood and a cooking surface;

FIG. 2 is a simplified block circuit diagram of components of the voice operating unit of FIG. 1; and

FIG. 3 is a diagrammatic illustration of an operation mode of the motion sensor of FIG. 1.

### DESCRIPTION OF THE PREFERRED EMBODIMENTS

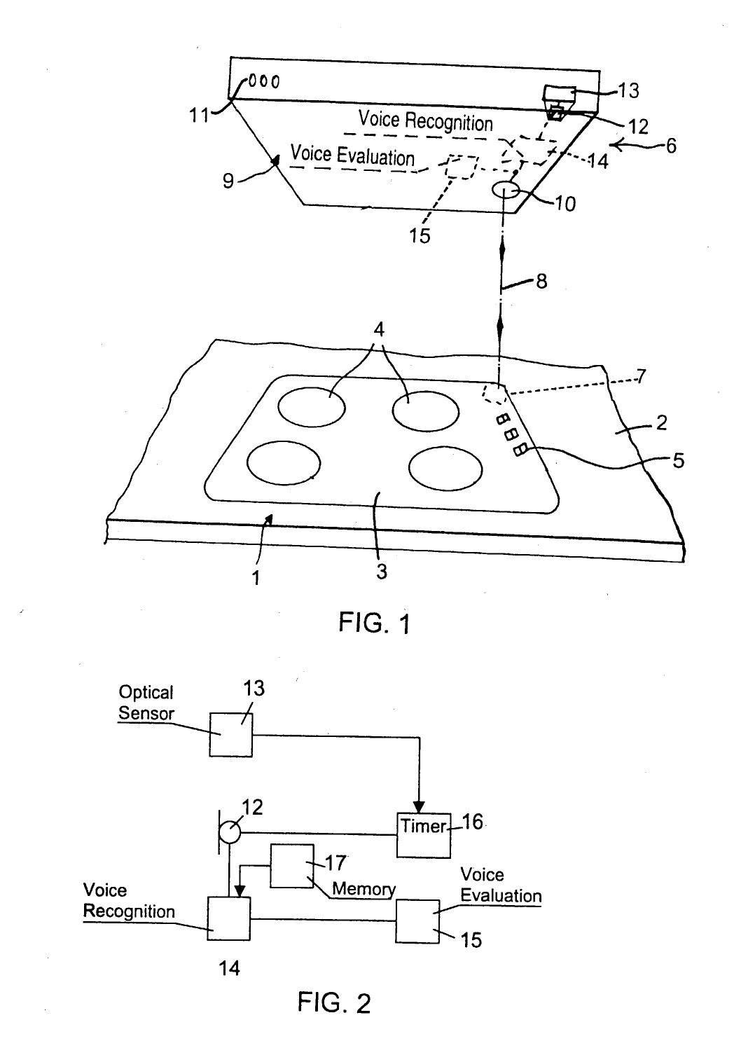

Referring now to the figures of the drawings in detail and first, particularly to FIG. 1 thereof, there is shown a cooking surface 1 mounted in a cutout of an operating plate 2. Various cooking zones 4 are marked on a cooking surface plate 3, which is made from glass ceramic, in particular. Depending on the inputs through an operating and display unit 5 of the cooking surface 1, non-illustrated cooking vessels that are to be placed on the cooking zones 4 can be heated in a conventional manner by heating elements that are disposed underneath the cooking surface plate 3, through a control unit. Here, the operating and display unit 5 is present for reasons of comfort and safety. It may be reduced to the minimum that is prescribed for safety equipment, in the case of which the overall configuration also has a voice operating unit 6 as described below.

In the cooking surface 1 there is also a transceiver unit 7, which communicates in a conventional manner through a transmission link 8, operating in a wireless fashion, with a ventilator hood 9 disposed above the cooking surface 1. The transmission link 8 can be implemented, for example, as a radio link in this case. To communicate with the cooking surface 1, the ventilator hood 9 has a transceiver unit 10. The ventilator hood 9, likewise, has operating and display elements 11, through which functions of the ventilator hood 9 are actuated and/or displayed. To permit a voice input, the voice operating unit 6 has a microphone 12 that is disposed spatially downstream of an optical sensor 13. The sensor 13 is configured as a motion sensor and reacts to moving infrared sources. When the sensor 13 has detected such a moving infrared source, that is to say, a human, it switches on the microphone 12. Signals picked up by the microphone 12 are fed to a voice recognition unit 14. The voice recognition unit 14 is connected to a voice evaluation unit 15, which derives a signal for controlling the ventilator hood 9 and/or the cooking surface 1 from the received voice signal. In the latter case, this signal is transmitted to the cooking surface 1 through the transmission link 8.

The mode of operation of the voice operating unit is explained below with the aid of the block diagram of FIG. 2. When the optical sensor 3 has detected a moving heat source, the sensor 3 generates an output signal for a timer 16. The timer 16 switches on the microphone 12 for a period of time that is prescribed or can be prescribed by the operating elements 11, and, so, the microphone picks up voice signals. The microphone 12 passes the voice signals on to the voice recognition unit 14, which checks whether a competent person attending for the purpose of giving commands is present or the person is a stranger. Stored for such a purpose in a memory 17 associated with the voice recognition unit 14 are speech patterns of those persons who come into consideration as operators for operating the voice operating unit 6. Thus, stranger is defined, for example, as a person who is not an operator. If the voice recognition unit 14 has been able to recognize such a person as one of the operators, the voice signals are passed on to the voice evaluation unit 15, in which the suitable signal is, then, generated to actuate the ventilator hood 9 and/or the cooking surface 1.

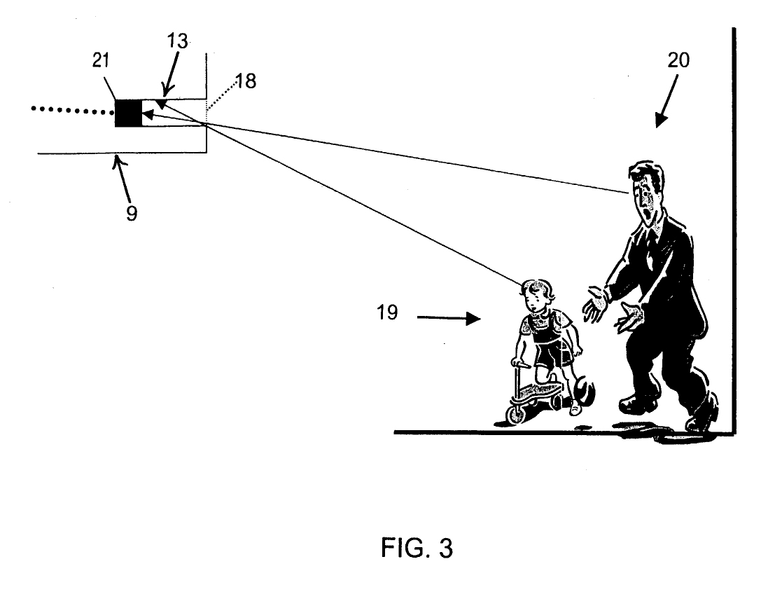

The optical sensor 13 illustrated in FIG. 3 is disposed behind a diaphragm 18 that ensures that the sensor 13 has the desired directional characteristic. The distance of the sensor 13 from the diaphragm 18 sets the size of the detection region. As a result of the diaphragm 18, the infrared light emitted by a child 19 is no longer detected by the sensor 13, whereas the infrared light generated by an adult 20 passes through the diaphragm 18 onto a sensitive surface 21 of the sensor 13 and, thereby, activates the timer 16. The microphone 12 is, then, activated for picking up voice signals for a specific period of time.

The diaphragm 18 is, preferably, also adjustably disposed, in order to adapt it to the size of operators that come into consideration as well as to the desired spatial directions from which signals are to be received.

It holds, in general, that the geometry of the sensor 13 can be of variable configuration so that the angle of detection can be varied through the diaphragm 18 and the range of detection can be varied through a non-illustrated joint.

The intervention of the timer 16 results in a time control by which the influence of interference variables is strongly suppressed. Noise sources not situated in the range of the sensor 13 are completely suppressed. The voice recognition unit 14 checks whether or not the acoustic signal can originate from a “living” source. Maloperation by children is largely constrained or even excluded. In accordance with the invention, it may be assumed that a real “command source,” that is to say, an operator, is present in the room. It is, thereby, possible to use voice operation even for safety-relevant systems such as cookers and ovens because the commands are checked by the competent person present. It is possible largely to suppress inadvertent actuation of the system.

I claim:

1. In an electrical household appliance, a voice-activation unit comprising:
a voice operating unit having:
a microphone;
a motion detector for detecting motion and generating a motion detected signal when motion is detected, said motion detector connected to said microphone and supplying said motion detected signal to said microphone; and
said microphone being switched on only during reception of said motion detected signal.

2. The voice-activation unit according to claim 1, wherein said motion detector is an infrared signal receiver.

3. The voice-activation unit according to claim 1, wherein said motion detector is a sensor reacting to signal changes.

4. The voice-activation unit according to claim 1, wherein said motion detector is a signal change-reacting sensor.

5. The voice-activation unit according to claim 1, including a timer connected to said microphone and to said motion detector, said timer setting an on period of said microphone, and said motion detector activating said timer to set said on period of the microphone.

6. The voice-activation unit according to claim 5, wherein said motion detector has a directional characteristic limiting an area of a room detectable by said motion detector.

7. The voice-activation unit according to claim 5, wherein said motion detector has a directional characteristic limiting detection in a room to above a prescribed height.

8. The voice-activation unit according to claim 6, wherein:
said motion detector is a sensor reacting to signal changes; and
said sensor has a diaphragm through which infrared radiation is passed to said sensor.

9. The voice-activation unit according to claim 1, wherein:
said motion detector is an infrared sensor reacting to signal changes; and
said sensor has a diaphragm through which infrared radiation is passed to said sensor.

10. The voice-activation unit according to claim 1, wherein said motion detector detects motion in a room and has a directional device limiting detection by said motion detector to a given area of the room.

11. The voice-activation unit according to claim 10, wherein said directional device limits detection by said motion detector to a given area of the room lying above a prescribed height.

12. The voice-activation unit according to claim 10, wherein:
said motion detector is a sensor that reacts to signal changes; and
said sensor has a diaphragm through which infrared radiation is passed to said sensor.

13. The voice-activation unit according to claim 10, wherein:
said motion detector is a sensor reacting to signal changes; and
said sensor has a diaphragm through which infrared radiation is passed to said sensor.

14. The voice-activation unit according to claim 1, wherein:
said voice operating unit has a memory storing at least one voice spectrum;
a voice recognition unit:
is connected to said microphone and to said memory; and
is programmed to recognize said at least one voice spectrum; and
a voice evaluation unit is connected to said voice recognition unit and is activated only when said voice recognition unit recognizes said stored voice spectrum.

15. In a ventilator hood, a voice-activation unit comprising:
a voice operating unit having:
a microphone;
a motion detector for detecting motion and generating a motion detected signal when motion is detected, said motion detector connected to said microphone and supplying said motion detected signal to said microphone; and
said microphone being switched on only during reception of said motion detected signal.

16. A method for operating a household appliance, which comprises:
detecting movement of a person or an object with a motion detector for detecting motion and generating a motion detected signal when the motion is detected;
switching on a microphone for a prescribed period of time dependent upon the motion detected signal;
analyzing voice signals detected by the microphone; and
passing the detected voice signals to a voice evaluation unit only when a voice is detected and activating a function of the household appliance.

17. The method according to claim 16, which further comprises carrying out the activating step by activating a function of the household appliance with the voice evaluation unit.

18. A method for operating a ventilator hood, which comprises:
detecting movement of a person or an object with a motion detector for detecting motion and generating a motion detected signal when the motion is detected;
switching on a microphone for a prescribed period of time dependent upon the motion detected signal;
analyzing voice signals detected by the microphone; and
passing the detected voice signals to a voice evaluation unit only when a voice is detected and activating a function of the household appliance.

19. A method for operating a ventilator hood, which comprises:
detecting movement of a person or an object with a motion detector for detecting motion and generating a motion detected signal when the motion is detected;
switching on a microphone for a prescribed period of time dependent upon the motion detected signal; and
analyzing voice signals detected by the microphone and, if a voice is detected, passing the detected voice signals to a voice evaluation unit for evaluation and activating a function of the household appliance with the voice evaluation unit dependent upon the evaluation of the detected voice signals.
